(19) United States
(12) Patent Application Publication
(10) Pub. No.: US 2018/0232303 A1
(43) Pub. Date: Aug. 16, 2018

(54) Method and Apparatus for Controlling a Non-Volatile Digital Information Memory

(71) Applicant: HYPERSTONE GMBH, Konstanz (DE)

(72) Inventor: Martin Roeder, Konstanz (DE)

(21) Appl. No.: 15/665,709

(22) Filed: Aug. 1, 2017

(30) Foreign Application Priority Data
Feb. 16, 2017 (DE) 102017103214.2

(51) Int. Cl. G06F 12/02; G11C 16/34; G11C 16/10; G11C 29/04

(52) U.S. Cl. CPC G06F 12/0246; G11C 16/34; G06F 2212/72; G11C 29/04; G11C 16/102

(57) ABSTRACT

Embodiments are related to controlling a non-volatile digital information memory, such as a flash memory, by means of a memory controller. More specifically, embodiments are related to a method of controlling the information memory, a computer program being configured to perform the method, a memory controller for performing the method, and/or a memory system comprising such a memory controller.

### CROSS REFERENCE TO RELATED APPLICATIONS

The present application claims priority to German Patent Application No. 10 2017 103 214.2 entitled “Method And Apparatus For Controlling A Non-Volatile Digital Information Memory”, and filed Feb. 16, 2017. The entirety of the aforementioned reference is incorporated herein by reference for all purposes.

### FIELD OF THE INVENTION

Embodiments are related to controlling a non-volatile digital information memory, such as a flash memory, by means of a memory controller. More specifically, embodiments are related to a method of controlling the information memory, a computer program being configured to perform the method, a memory controller for performing the method, and/or a memory system comprising such a memory controller.

### BACKGROUND

Nowadays, non-volatile digital information memory, such as flash memory, is found in many electronic devices, for example in communication technology and automotive technology. Non-volatile information memory (NVM) is characterized by the fact that unlike volatile information memory (VM), such as random access memory (RAM), it does not lose the data stored therein, if its power supply is discontinued. However, generally NVM show some peculiarities that must be taken into account for their control.

Particularly, this includes that in some NVM types, notably in flash memory, the individual memory cells cannot be erased or reprogrammed individually, but instead this is only possible blockwise for respective predefined blocks of memory cells. For example, in order to reprogram one or more memory cells pertaining to a same block in a flash memory, the whole block must be erased at first and then reprogrammed with a new desired data pattern that includes both the unmodified data of the other cells and the modified data of the memory cells to be reprogrammed.

Furthermore, in some types of NVM, particularly in flash memory, the number of erasure operations and consequently also programming operations per block that can be carried out in such an NVM during its lifetime (“cycle number” or “endurance”) is limited due to the physical structure of the NVM. For addressing such a digital information memory, devices accessing the information memory, which are commonly referred to as “host” (such as computers and machine controllers) make use of so-called “logical” addresses, which however typically do not coincide with the physical addresses of the information memory and which may particularly be defined operating system-dependent. Accordingly, in order to control information memory, the logical addresses must be translated into their respective physical ad-dresses, which is frequently referred to as “address mapping” or in short “mapping”, and which typically is one of the tasks of the memory controller controlling the information memory, specifically of a flash controller in the case of flash memory.

In some cases, the assignment of the logical addresses to the physical addresses of the information memory is also stored in an information memory in the form of mapping or assignment data in the form of a so-called mapping table. Assignment data for NVMs are typically stored on the one hand in the NVM itself but also in an additional second, usually volatile memory (VM, particularly RAM). The use of this additional volatile memory has the advantage that modifications of the assignment data, which occur during writing or erasing data in the NVM, initially only need to be updated in the assignment data stored in the VM, which on the one hand typically has shorter access times than the NVM and on the other hand does not have the latter's limited endurance. The contents of the assignment data in the VM and the NVM are then synchronized, when the memory area designated for storing the assignment data encounters its capacity limit or when the memory system is switched off in a controlled way, such that thereafter the assignment data representing the current status is also present in the NVM. In the event of a deviation between the (possibly obsolete) assignment represented by the assignment data stored in the NVM from the corresponding (current) assignment represented by the assignment data stored in the VM, the degree of such a deviation is in the technical terminology frequently also referred to as “Dirtiness”.

### SUMMARY

Embodiments are related to controlling a non-volatile digital information memory, such as a flash memory, by means of a memory controller. More specifically, embodiments are related to a method of controlling the information memory, a computer program being configured to perform the method, a memory controller for performing the method, and/or a memory system comprising such a memory controller.

This summary provides only a general outline of some embodiments of the invention. The phrases “in one embodiment,” “according to one embodiment,” “in various embodiments”, “in one or more embodiments”, “in particular embodiments” and the like generally mean the particular feature, structure, or characteristic following the phrase is included in at least one embodiment of the present invention, and may be included in more than one embodiment of the present invention. Importantly, such phrases do not necessarily refer to the same embodiment. Many other embodiments of the invention will become more fully apparent from the following detailed description, the appended claims and the accompanying drawings.

### BRIEF DESCRIPTION OF THE FIGURES

A further understanding of the various embodiments of the present invention may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 shows schematically a host connected to a memory system having a memory controller, a first information memory NVM and a second information memory VM and an energy storage, according to some embodiments of the present inventions;

FIG. 2 shows a flow diagram illustrating various embodiments of the methods in which an interface for transmitting a signal is provided between a host and the memory controller that indicates a present, upcoming or imminent impairment of the regular power supply of the memory system;

FIG. 3 shows a flow diagram illustrating other embodiments of the methods in which the maximum allowed dirtiness with respect to the assignment data in the NVM is controlled using a predetermined criterion;

FIG. 4 shows a flow diagram illustrating various embodiments of the methods in which the two methods of FIGS. 2 and 3 are combined; and

FIG. 5 shows a flow diagram illustrating yet other embodiments of the methods where the method of FIG. 4 is modified such that the use of an energy storage is dispensed with.

### DETAILED DESCRIPTION OF SOME EMBODIMENTS

Embodiments are related to controlling a non-volatile digital information memory, such as a flash memory, by means of a memory controller. More specifically, embodiments are related to a method of controlling the information memory, a computer program being configured to perform the method, a memory controller for performing the method, and/or a memory system comprising such a memory controller.

Various embodiments of the present inventions relate to methods for controlling a digital non-volatile memory (NVM), such as, but not limited to, a flash memory, by means of a memory controller. Such methods include an updating process, in which the memory controller updates, by a respective controlling of the NVM, first assignment data being stored in the NVM and representing an assignment between the logical memory addresses being addressable by a host through the memory controller and physical memory addresses of the NVM, such that as a result the assignment represented by the first assignment data coincides with an assignment between the logical memory ad-dresses and physical addresses of the NVM that is currently actually used by the memory controller for addressing the NVM, and which is at least partly stored in a volatile memory (VM) by means of respective second assignment data representing it. Furthermore, the method comprises an examination process, in which a determination is made, as to whether a predefined criterion is met that characterizes a potential loss of the second assignment data with regard to its occurrence and/or the degree of deviation of the assignment represented by the second assignment data from the assignment represented by the first assignment data. Thereby, the updating process is triggered when the examination process determines that the criterion is met.

As used herein, the phrase “memory controller” or “memory controller circuit” are used in their broadest sense to mean a digital circuit that is configured to control the flow of data to and from a digital information memory. A memory controller may be implemented as a separate semiconductor chip or chipset or may be integrated into another chip, particularly into the actual information memory itself or in a microprocessor that can access the information memory.

In various instances of the aforementioned embodiments, the second information memory is a volatile information memory and may particularly be implemented as a RAM. The volatile information memory may particularly be integrated into the memory controller or be a separate component of the memory system connected to the memory controller.

If in a conventional memory system that comprises, in addition to a first information memory implemented as an NVM and a memory controller controlling same, as described above, a second information memory VM for the temporary and at least partial storage of the assignment data for the NVM, a loss of the assignment data stored in the VM occurs, before the corresponding assignment data in the NVM could be synchronized with the current assignment data in the VM, only the obsolete assignment data in the NVM remains, while the current assignment data in the VM is lost. Such a situation can occur, for example, due to an uncontrolled, particularly sudden power failure, if that VM is a volatile memory or a writing process in the VM is not completed yet at the time the power supply to the VM is removed. When the memory system is then activated again at a later point in time, the last valid state of the assignment data can thus no longer be reconstructed from the lost memory con-tents of the VM, but only a previously stored, obsolete state from the memory con-tents retained in the NVM. Depending on the design of the memory system, the desired mapping state that was actually present immediately before the switching off can then be either not at all reconstructed, or only with increased effort from the actual user data itself that is also stored in the NVM and corresponds to the address area covered by the mapping. In particular, the start-up of a memory system which was previously switched off in an uncontrolled manner without prior synchronization of the most recently valid assignment data from VM and NVM is significantly slower, so that longer start-up times occur than in the case of a controlled shutdown, in which such synchronization is completed before the power supply to the memory system is discontinued.

In some embodiments of the present inventions, the occurrence of an undesirable data loss condition and in particular of increased startup times can be counteracted by examining, by means of the criterion, whether an occurrence of a loss of the second assignment data in the VM has to be expected and/or whether, if applicable, such data loss of the second assignment data would be beyond an acceptance threshold determined by means of the criterion. In both cases, when the criterion is met, the updating process is triggered to prevent such imminent data loss.

If a data loss actually occurs at VM, for example because of a sudden power failure, then (i) this is either irrelevant because the first assignment data has already been brought up to date due to the immediately preceding updating process triggered by means of the examining process, or (ii), if a change in the second assignment data has already taken place since the last updating process, the extent of the corresponding data loss always remains within the limits defined by the criterion so that the negative effects on the startup time of the NVM for a subsequent startup are limited to a predetermined and still acceptable level.

It should noted that while a number of embodiments are described herein, that these embodiments may stand separate from one another or may be combined with one another or with other aspects discussed herein.

In one or more instances of the aforementioned embodiments, in the examination process it is determined whether the criterion is fulfilled, whether an impairment of the power supply of the memory controller and/or of the VM is already present, upcoming or imminent. The impairment of the power supply may in particular concern a discontinuation of the power supply, its decrease or its transition into an unstable state, so that in any case no continuous power supply of the VM sufficient to maintain the data of the second assignment data is ensured. In this way, it can be recognized, in particular by means of a corresponding monitoring of the power supply, whether a power-supply-related data loss occurs with respect to the second assignment data stored in the VM or is imminent. The monitoring may also include or concur with a monitoring of the power supply to the NVM. Thus, the power supply of the NVM, which is also required for the updating process, can be advantageously taken into ac-count during the examination process and, in particular, included in the monitoring.

In some instances of the aforementioned embodiments, in the examination process the potential impairment of the power supply is recognized by means of receiving a signal transmitted to the memory controller by a host being signal-connected to the memory controller via an interface, the signal indicating such a present, upcoming or imminent impairment. In this way, the host, which in some situations may already have recognized the upcoming impairment of the power supply of the VM before the memory controller does, may specifically and in particular without further time loss inform the latter and thus cause a triggering of the updating process at the memory controller. The signal connection between the host and the memory controller may take place via an interface which is provided between the two, which may be provided either dedicated to this purpose or else for other communication between the host and the memory controller. The host may in particular be designed as a unit separate from the memory controller, for example as a computer unit (e.g. control unit for a system or personal computer), or else as a unit integrated with the memory controller. The first and/or second digital information memory may also be part of such an integrated unit. It may be implemented in particular as a system-on-chip (SOC) or may contain several separate chips, which are however combined in a common package.

In some cases, the signal for indicating the impairment of the power supply includes at least one of the following control commands directed to the memory controller: (i) a control command specified according to an industry standard; (ii) an application-specific control command; (iii) a control command specifically defined for initiating the updating process. Thus, it is possible to provide both application- and manufacturer-independent standardized control commands for signaling, so as to allow for the greatest possible compatibility among the individual components of such memory system comprising a memory controller and a plurality of information memories, as well as application- or manufacturer-specific control commands, which allow for an adaptation to specific circumstances of specific solutions even beyond that.

In various instances of the aforementioned embodiments, in the examination process the potential impairment of the power supply is determined by means of, for example, regularly and continuously, monitoring the power supply by the memory controller. This may include, for example, a detection of the level of a supply voltage corresponding to the power supply. In this manner, the memory controller is enabled to detect any such impairment of the power supply also independently of the host and thus, if necessary, to react even faster or even in the absence or failure to appear of a signaling from the host by means of a triggering of the updating process. However, it is equally conceivable for the memory controller and the host to be integrated together in a single device or a single system. The monitoring of the power supply, which is effected by means of the memory controller, may thus also include monitoring the power supply of the host, in particular both at the same time.

In one or more instances of the aforementioned embodiments, if an impairment of the power supply is determined, an energy storage is used instead of or in addition to the monitored power supply for supplying power to the memory controller and the VM, optionally also the NVM, for executing the updating process. The energy storage may in particular comprise one or more buffer capacitors or batteries. In this way, the loss of assignment data is countered not only by a timely triggering of the updating process, but also by its energy-related safeguarding, so that the updating process may be successfully completed before a sufficient power supply of the VM is discontinued so that the updating of the first assignment data can be achieved, even if the impairment of the regular power supply, without the addition of such an additional energy storage, would no longer allow the completion of the updating process.

In some instances of the aforementioned embodiments, the criterion is defined as a function of the degree of deviation of the assignment represented by the first assignment data from the corresponding assignment represented by the second assignment data. In this way, it is possible to define by means of the criterion a threshold for the degree of deviation, which corresponds to the maximum loss of second assignment data in the case of a data loss in the VM before execution of an updating process and thus al-lows this maximum loss to be reduced to a still acceptable degree. As far as the first assignment data and the second assignment data describe the mapping between the logical memory addresses and the physical memory addresses in the same way (so that immediately after the updating process the first and the second assignment data are identical, at least for an address area covered by both), the degree of the deviation may in particular be determined in a simple manner by means of a determination of the quantitative differences between the assignment data. In such a case, this can be done, in particular, by counting the different bits or other data units when comparing the first and second assignment data, without having to deal with the meaning of the assignment in terms of content.

In various instances of the aforementioned embodiments, the criterion is defined such that it is met both when in the examination process a present, upcoming or imminent impairment of the power supply is determined (as has already been de-scribed above), as well as when the degree of deviation of the assignment represented by the first assignment data from the corresponding assignment represented by the second assignment data reaches or exceeds a predetermined thresh-old. Thus, the advantages of the two previously mentioned variants, which, on the one hand, are based on detecting an impairment of the power supply and thus a possible actual occurrence of a data loss with respect to the second assignment data, and, on the other hand, serve to preventively limit the extent of the lost data resulting in the event of such a data loss, may be combined in order to avoid the risk of an undesirable increase of the start-up times and of the associated effort to “re-pair” the assignment data of the NVM.

In other instances of the aforementioned embodiments, the criterion is defined with regard to the degree of deviation of the assignment represented by the first assignment data from the corresponding assignment represented by the second assignment data as a function of one or more of the following variables: (i) a number of write operations in the NVM that have occurred since the last update; (ii) a number of erasure operations in the NVM that have occurred since the last update; (iii) a period of time that has elapsed since the last execution of the updating process; (iv) a data quantity indicating a degree of change in the second assignment data since the last execution of the updating process. All of the aforementioned variables (i) to (iv) have in common that they typically correlate with the degree of deviation of the assignment represented by the first assignment data from the corresponding assignment represented by the second assignment data and thus are suitable as indicators respectively measures for such a degree of deviation and can also be determined with little technical effort. Optionally, the criterion may additionally be defined as a function of one or more further variables.

In yet other instances of the aforementioned embodiments, the criterion is configurable by means of a parameterization in relation to the degree of deviation of the assignment represented by the first assignment data from the corresponding assignment represented by the second assignment data. In this way, it is possible to adjust the permitted degree of deviation (Dirtiness), which can maximally occur before the criterion is fulfilled and thus the updating process is triggered, by means of the parameterization. The higher the permitted degree of deviation is, the less is typically the processing effort associated with the memory management, as well as the wear of the NVM occurring with respect to the endurance, and vice versa. Thus, the configuration allows for a balancing between on the one hand the performance of the memory, in particular during reading and writing, and on the other hand the maxi-mum startup time. In particular, this may be done application-specifically, since different, in particular individual, considerations may be desirable for different applications or use cases. For example, the same NVM may support applications that only allow very short startup times but allow for slightly reduced read/write performance while on the other hand, it may provide full read/write performance to other applications that require less stringent requirements to the startup time. Also, the configuration within the same application may vary in time and in particular for different periods of time.

In various instances of the aforementioned embodiments, the updating of the first assignment data in the updating process comprises transferring the second assignment data from the VM to the first assignment data in the NVM at least in part. This is particularly useful, if the first assignment data and the second assignment data describe the mapping between the logical memory addresses and the physical memory address-es in the same way so that the first assignment data can be updated, at least in part, by using the corresponding second assignment data as a replacement, particularly by overwriting the corresponding first assignment data. Thus, the updating of the first assignment data can be carried out particularly efficiently, in particular by saving time and/or processing effort.

Yet other embodiments of the present inventions relate to a computer program configured to (i) be executed on one or more processors of a memory controller for controlling a non-volatile digital information memory, NVM, in particular a flash memory, and (ii) cause the memory controller to execute the method according to the first aspect of the invention, in particular according to one or more of the embodiments and further developments described herein. The computer program product may, in par-ticular, be provided in the form of a non-transient data medium on which one or more programs for executing the method are stored. In some cases, this is a data carrier, such as a CD, a DVD or a flash memory module. This can be particularly advantageous if the computer program product is tradeable as such or can be used by the user of the memory controller or memory system itself for programming same. Alternatively, or additionally, the computer program may also be loadable as a file on a data processing unit, in particular on a server, and via a data link into the memory controller or an external memory allocated to it (e.g. via download via the Internet or a dedicated data connection).

Yet further embodiments of the present inventions relate to a memory controller for controlling a non-volatile digital information memory (NVM), (e.g., a flash memory), the memory controller being configured to perform using one or more processes set forth in relation to the embodiments and corresponding instances discussed above. In some cases, the memory controller may be equipped with, or at least have access to, a computer program having instructions executable by the memory controller to perform using one or more processes set forth in relation to the embodiments and corresponding instances discussed above

Additional embodiments of the present inventions relate to a memory system including: (i) a non-volatile digital first information memory (NVM) (e.g., a flash memory); (ii) a, in particular volatile, second information memory, VM; and (iii) a memory controller according to the third aspect of the invention configured to control the NVM using the VM according to the method according to the first aspect of the invention, particularly according to one or more of its embodiments and further developments described herein.

In some instances of the aforementioned embodiments, the memory system further includes an energy storage for the at least temporary supply of the memory controller, the NVM and the VM with power, the energy storage being independent from an external power supply to the memory system. The energy storage may in particular comprise one or more buffer capacitors or batteries. In this way, the loss of assignment data can be countered not only by a timely triggering of the updating process, but also by its energy-related safeguarding, so that the updating process may be successfully completed before a sufficient power supply of the VM is discontinued so that the updating of the first assignment data can be achieved, even if the impairment of the regular power supply, without the addition of such an additional energy storage, would no longer allow the completion of the updating process.

### LIST OF REFERENCE SIGNS

1 memory system
2 memory Controller
2a processor
2b internal memory
3 first, non-volatile information memory, NVM
4 second, volatile information memory, VM
5 energy storage
6 switch, in particular circuit breaker, controlled by the memory controller 2
7 interface
8 host
A address bus
C control bus
D data bus
P supply bus
A1 address line host—memory system
C1 control line host—memory system
D1 data line(s) host—memory system
P1 power supply line—memory system

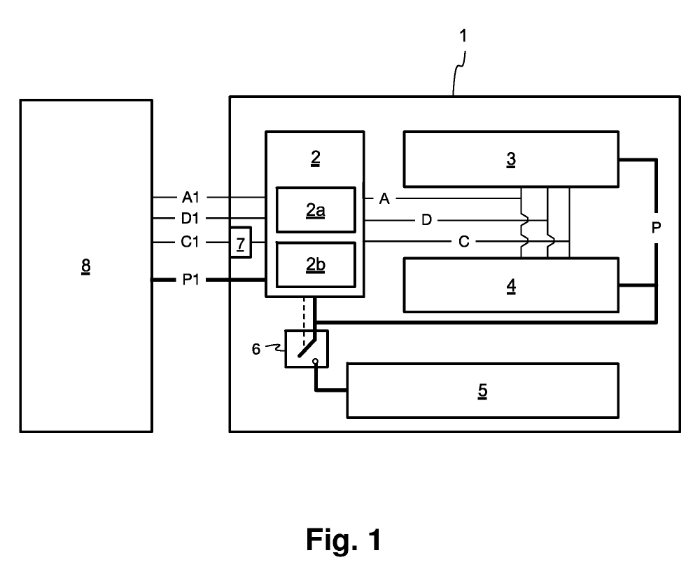

Referring first to FIG. 1. It shows a memory system 1 according to an embodiment of the inventions which is connected via an address line A1, a data line D1, a control line C1 as well as a power supply line P1 to a host 8 which uses the memory system 1 and in particular has read and write access thereto. One or more, in particular all, of the aforementioned lines may also be implemented in each case by means of a plurality of individual lines.

The memory system 1 has a memory controller 2, which in turn has a processor unit 2a with one or more processors as well as an internal memory 2b. In the internal memory 2, in particular, a computer program may be stored which contains instructions which cause the memory controller 2 to perform the method according to the invention. The memory controller 2 is connected via an address bus A, a data bus D and a control bus C both to a first, non-volatile information memory 3 (NVM), e.g. a flash memory, and to a second, volatile information memory 4 (VM), for example a DRAM memory. The NVM 3 serves in this case primarily as a data memory, while the VM 4, in any case also serves as a fast buffer for assignment data (mapping data), which represent an assignment between the logical and the physical memory addresses of the NVM 3. In addition, the NVM 3 also stores its assignment data itself, but not as frequently as the VM 4, so that there may be deviations between the assignment data stored NVM 3 and the assignment data stored in the VM 4, especially after write accesses. The degree of deviation of the corresponding assignments in NVM 3 and VM 4 at a given time is also referred to as “dirtiness”.

However, in some embodiments, the second information memory 4 may also coincide with the internal memory 2b of the memory controller 2, and thus already be implemented by the latter. In this case, all statements herein that relate to the VM 4 apply accordingly to the internal memory 2b.

Furthermore, the memory system 1 comprises an energy storage 5, which may be implemented in particular by means of a buffer capacitor and/or a battery, and which serves for supplying the memory system with power, if the external power supply provided by the host 8 (or, where applicable, another external power supply, not shown) via the power supply line P1 is affected, in particular has discontinued. The energy storage 5 is connectable via a switch 6, which may be implemented in particular as a power switch, to a supply bus P, which supplies both the memory controller 2, and the two information memories NVM 3 and VM 4 with power.

As a rule, the power required for the operation of the memory system is supplied to it via the power lines P1, while the energy storage 5 is decoupled from the supply bus P by the switch 6. However, if the external power supply via the supply line P1 (or otherwise) is impaired or no longer available, the switch 6 being controlled by the memory controller 2 can be closed so as to couple the energy storage 5 to the sup-ply bus P for supplying power to the memory system 1 from the energy storage 5 and thus independently or in addition to the external power supply.

The address line A1 is for the host to access the NVM3 and optionally also the VM 4 by means of logical memory addresses via the memory controller 2, which converts them to physical memory addresses. The data line D1 is used accordingly to transfer the data required for write or read access from the host 8 to the memory system 1 or in the reverse direction. Via the control line C1, which is guided on the memory system 1 via an interface 7, the host may send control commands to the memory system 1, i.e. to the memory controller 2. In particular, a control command may be provided, which allows the host 8 to signal to the memory system 1 that a shutdown, or an otherwise justified loss of the power supply via the power supply power P1 is imminent or immediately upcoming. The interface 7 may be particularly configured to receive standardized control commands. In some cases, the interface itself is, unlike in FIG. 1, even part of the memory controller 2.

Additionally or alternatively, the memory controller 2 may also be adapted to monitor itself the power supply provided via the supply lines P1, for example by means of a monitoring of the corresponding supply voltage. If then during the monitoring an impairment of the power supply is detected, such as a drop in the supply voltage or significant voltage fluctuations, the memory controller 2 can then control the switch 6 such that the memory system 1 is supplied additionally or alternatively by the energy storage 5 and in the meantime the assignment data stored in the NVM 3 can be updated based on the assignment data stored in the VM 4, i.e. can be brought to the latest status, before also the power supply from the energy storage 5 runs low. Accordingly, it is advisable to dimension the energy storage 5 in the design of the memory system 1 so that it can provide enough energy for the completion of such an update, even if a maximum expected or allowed degree of deviation (dirtiness) between the assignment data in the NVM 3 and that in the VM4 is present.

In the following explanation of example embodiments of the method according to the invention, reference is made to the example arrangement shown in FIG. 1, which reference is however not to be understood as a limitation.

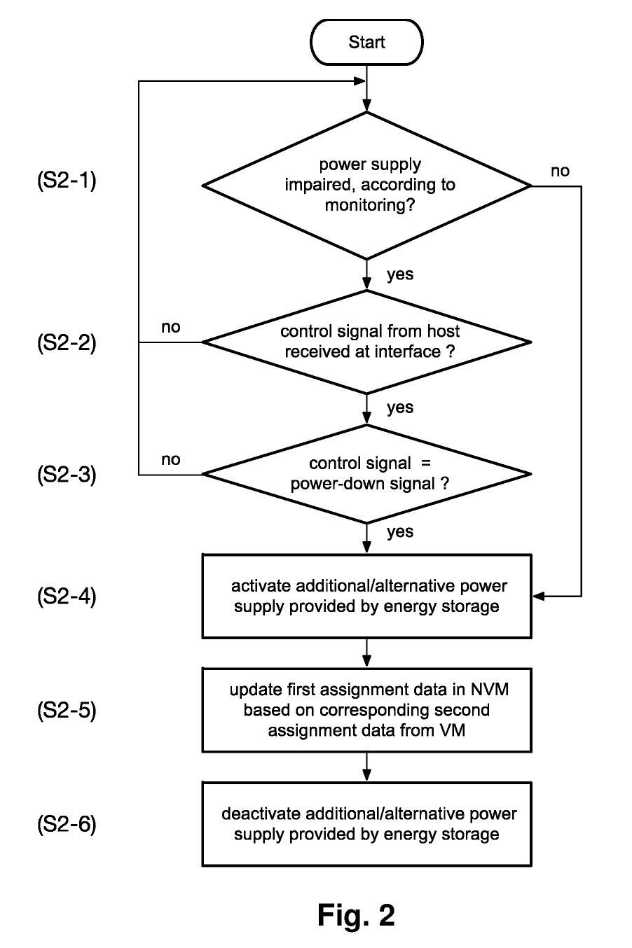

FIG. 2 shows a first embodiment of the method according to the invention, wherein a signal, such as in form of a corresponding control command, can be transmitted between the host 8 and the memory controller 2 via the interface 7, which signal indicates an existing, upcoming or imminent impairment of the regular power supply (via P1) to the memory system 2.

In the method, which (like all further herein described methods according to the invention) is executable by the memory controller 2 and may be implemented in particular by means of a corresponding computer program being stored in the internal memory 2b and executable by the processor unit 2a, first in a step S2-1 the memory controller 2 determines, whether according to a periodically or continuously occurring monitoring of same the power supply of the memory system 1 suffers from an impairment, such as a reduction or significant fluctuation of the supply voltage. If this is the case (S2-1—no), i.e. if the power supply is not unimpaired, the method immediately proceeds to a further step S2-4, in which by means of a corresponding control of the switch S6, the additional or alternative power supply of the memory sys-tem 1 by means of the energy storage 5 is activated by closing the switch S6.

Otherwise (S2-1—yes) the method proceeds from step S2-1 to step S2-2, where a examination is performed as to whether a control signal, in particular a control command, has been received from the host at the interface 7. If this is not the case (S2-2—no), the method returns in a loop to the starting point, to be then executed again (at least optionally). Otherwise (S2-2—yes), in a subsequent step S2-3 a examination is performed as to whether the control signal indicates an impairment of the external power supply (power-down signal). If this is not the case (S2-2—no), the method also loops back to the starting point, while otherwise (S2-2—yes) the method proceeds to the already mentioned step S2-4, in which through closing switch 6 by an appropriate control the additional or alternative power supply of the memory system 1 through the energy storage 5 is activated. The control signal or control command may, in particular, be transmitted by the host 8, when its own, in particular external power supply drops, fluctuates significantly, or even discontinues. The steps S2-1 to S2-3 may collectively be referred to as examination step. Optionally, the step S2-1 may be absent in this, as in any of the further embodiments described in detail below. In addition, the steps S2-2 and S2-3 may also coincide.

Simultaneously with step S2-4 or subsequently to it, in a further step S2-5 (updating step) the assignment data stored in NVM 3 are updated on the basis of the corresponding second assignment data stored in VM 4. In particular, this may be done by transferring second assignment data from the VM 4 to the NVM 3, which is particularly useful, if the way in which the first and second assignment data are defined is identical. In other cases, it may be necessary for the transfer to at first convert by the memory controller 2 the assignment data from VM 4 into the format of the assignment data stored in NVM 3. Finally, after completion of the updating step S2-5, a further step S2-6 may follow, wherein the additional respectively alternative power supply of the memory system 1 through the energy storage 5 is deactivated again by means of a respective controlling of switch S 6 in order to open it again. The steps S3-4 and S3-6 are advantageous, because they serve to safeguard the energy supply for performing the updating step S2-5. However, in general, they may also be skipped, as far as a sufficient power supply for memory system 1 to perform the updating step can be ensured otherwise.

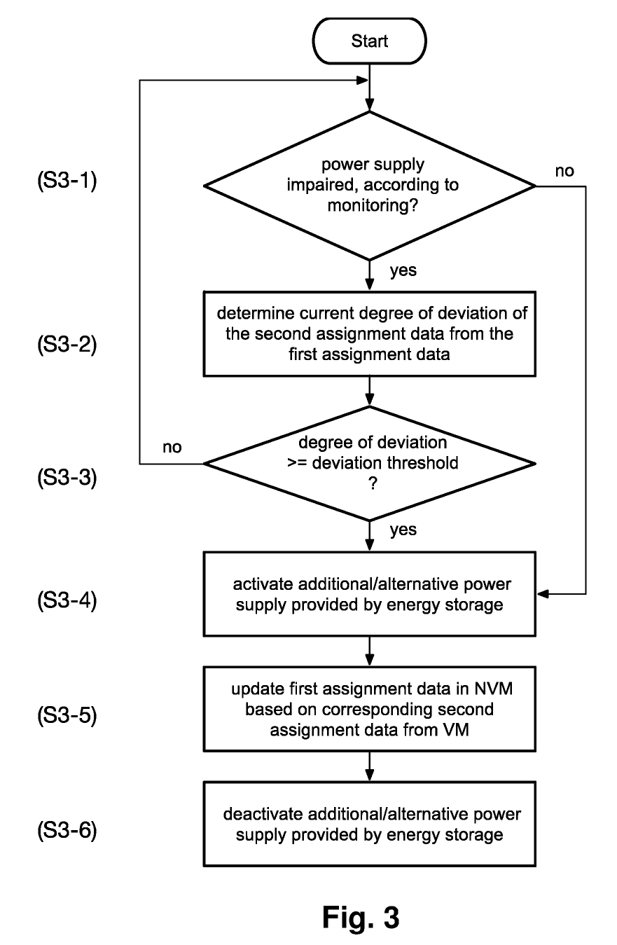

In FIG. 3, another embodiment of the method is illustrated using a flowchart. Here, too, it is first determined by the memory controller 2 in a step S3-1 whether the power supply of the memory system 1 according to a periodically or continuously performed monitoring of same is impacted by an impairment such as a drop or significant fluctuation of the supply voltage, and if this is not the case (S3-1—no) the method proceeds to step S3-4, which corresponds to step S2-4 of FIG. 2. In addition, the subsequent steps S3-5 and S3-6 correspond to steps S2-5 and S2-6 in FIG. 2, respectively, so that in order to avoid mere repetition reference is made to the respective above explanations.

The method of FIG. 3 thus differs from that of FIG. 2 in that the steps S2-2 and S2-3 were replaced by steps S3-2 and S3-4, while the rest of the method remains unmodified. When in the method according to FIG. 3 the step S3-2 is reached (S3-1—yes), then the current degree of deviation of the assignment data stored in VM 4 from the assignment data stored in VM 4 is determined. More specifically, the degree of deviation between the assignments (mappings) defined by the respective assignment data is determined, which however in the case illustrated here, where both the first and the second assignment data are defined respectively formatted in the same way, does not make any difference. Alternatively, step S3-2 may also occur at an earlier point in time, particularly simultaneously with or even before step S3-1.

Then, in subsequent further step S3-three, a test is performed as to whether the determined degree of deviation is beyond a predetermined deviation threshold char-acterizing a maximum allowed dirtiness. If this is not the case (S3-3—no), the meth-od returns in a loop to the starting point and may be run again from there. Otherwise (S3-3—yes) the method proceeds to step S3-4 and proceeds further as already described above with reference to FIG. 2, wherein and updating of the assignment data stored in NVM 3 occurs. The combination of steps S3-1 to S3-3 forms at examination step preceding updating step S3-5. Furthermore, steps S3-2 and S3-3 may also coincide.

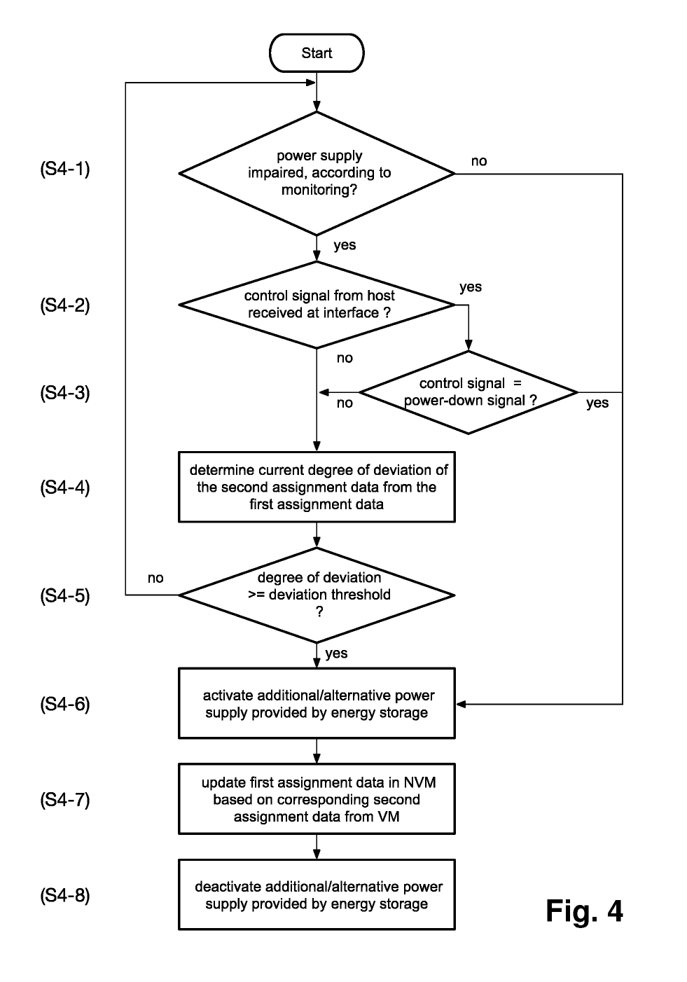

FIG. 4 illustrates a combination of the method embodiments of FIG. 2 and FIG. 3. In this case, step S4-1 again corresponds to step S2-1, steps S4-2 and S4-3 correspond to steps S2-2 and S2-3, and steps S4-6 to S4-8 correspond to steps S2-4 to S2-6 of FIG. 2. In addition, steps S4-4 and S4-5 correspond to steps S3-2 and S3-3 of FIG. 3. The sequence of steps S4-1 to S4-5 is optimized so that those tests, namely for the immediate impairment of the power supply of the memory system 1 (cf. step S4-1) respectively the upcoming or imminent impairment of the power supply as signaled by host 8 (cf. S4-2), to which, if appropriate, an immediate response should follow, take place before the general limitation of the dirtiness according to steps S4-4 and S4-5.

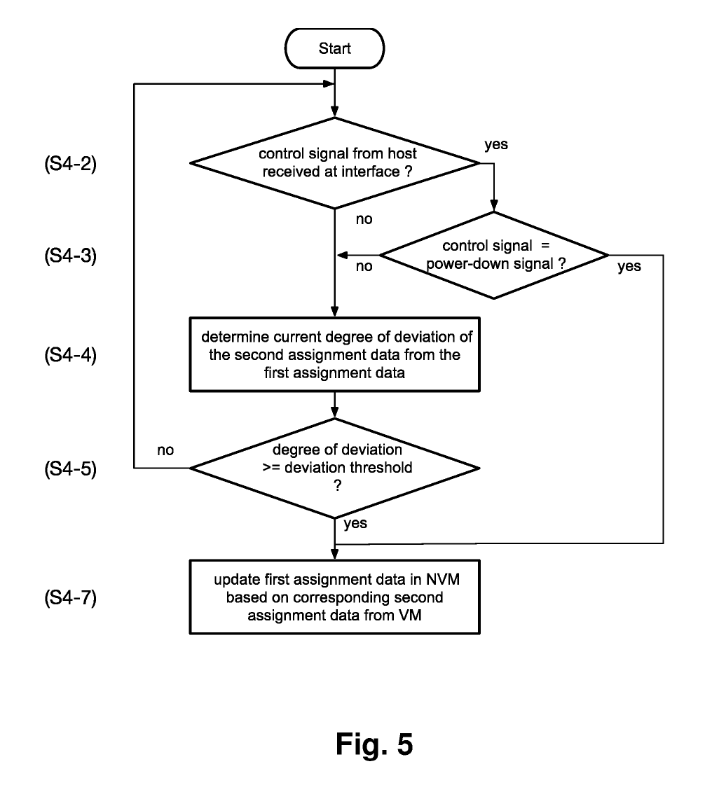

FIG. 5 illustrates a further embodiment, which arises from that described in connection with FIG. 4 in that the optional use of an energy storage 5 is absent. Otherwise, the method of FIG. 5 corresponds to that of FIG. 4, so that the respective previous description of FIG. 4 also applies here insofar as it does not relate to the energy storage 5.

While above at least one example embodiment of the present invention has been described, it has to be noted that a great number of variation thereto exists. Furthermore, it is appreciated that the described example embodiments only illustrate non-limiting examples of how the present invention can be implemented and that it is not intended to limit the scope, the application or the configuration of the herein-described apparatus' and methods. Rather, the preceding description will provide the person skilled in the art with instructions for implementing at least one example embodiment of the invention, wherein it has to be understood that various changes of functionality and the arrangement of the elements of the example embodiment can be made, without deviating from the subject-matter defined by the appended claims and their legal equivalents.

What is claimed is:

1. A method of controlling a first information memory, the method comprising:
using a memory controller circuit to:
perform an updating process where first assignment data being stored in the first information memory and representing an assignment between the logical memory addresses being addressable by a host through the memory controller circuit and physical memory addresses of the first information memory is updated such that the assignment represented by the first assignment data coincides with an assignment between the logical memory addresses and physical addresses of the first information memory that is currently actually used by the memory controller circuit for addressing the first information memory, and which is at least partly stored in a second information memory as respective second assignment data;
perform an examination process in which a determination is made, as to whether a pre-defined criterion is met that characterizes a potential loss of the second assignment data with regard to its occurrence and/or the degree of deviation of the assignment represented by the second assignment data from the assignment represented by the first assignment data; and
wherein the updating process is started upon determining that the criterion is met.

2. The method of claim 1, wherein the first information memory is a non-volatile memory (NVM), and wherein the second information memory is a volatile memory (VM).

3. The method of claim 2, wherein the examination process includes at least one process selected from a group consisting of: determining whether the criterion is fulfilled, and determining whether an impairment of the power supply of the memory controller circuit and/or of the VM is already present, upcoming or imminent.

4. The method of claim 3, wherein the examination process includes identifying the potential impairment of the power supply based at least in part on receiving a signal transmitted to the memory controller circuit by the host, and wherein the host is signal-connected to the memory controller circuit via an interface, the signal indicating a present impairment, upcoming impairment or imminent impairment.

5. The method of claim 4, wherein the signal for indicating the impairment of the power supply includes at least one of the following control commands directed to the memory controller circuit:
a control command specified according to an industry standard;
an application specific control command; and
a control command specifically defined for initiating the updating process.

6. The method of claim 3, wherein:
in the examination process the potential impairment of the power supply is determined at least in part by monitoring the power supply by the memory controller circuit.

7. The method of claim 3, wherein, if an impairment of the power supply is determined, an energy storage is used instead of or in addition to the monitored power supply for supplying power to the memory controller circuit and the VM for executing the updating process.

8. The method of claim 3, wherein the criterion is defined such that it is fulfilled both when an impairment of the power supply is determined, as well as when a degree of deviation of the assignment represented by the first assignment data from the corresponding assignment represented by the second assignment data reaches or exceeds a predetermined threshold.

9. The method of claim 1, wherein the criterion is defined as a function of a degree of deviation of the assignment represented by the first assignment data from the corresponding assignment represented by the second assignment data.

10. The method of claim 9, wherein the criterion is defined with regard to the degree of deviation of the assignment represented by the first assignment data from the corresponding assignment represented by the second assignment data as a function of one or more of the following variables:
a number of write operations in the NVM that have occurred since the last update;
a number of erasure operations in the NVM that have occurred since the last update;
a period of time that has elapsed since the last execution of the updating process;
a data quantity indicating a degree of change in the second assignment data since the last execution of the updating process.

11. The method of claim 9, wherein the criterion is configurable by means of a parameterization in relation to the degree of deviation of the assignment represented by the first assignment data from the corresponding assignment represented by the second assignment data.

12. The method of claim 2, wherein the updating of the first assignment data in the updating process comprises transferring the second assignment data from the VM to the first assignment data in the NVM at least in part.

13. A non-volatile memory system, the system comprising:
a memory controller circuit operable to:
determine a potential degradation of a second assignment data stored in a volatile memory (VM), wherein the potential degradation is indicated when a predefined criterion is fulfilled; and
update a first assignment data stored in a non-volatile memory (NVM) based at least in part on the determined potential degradation of the second assignment data, wherein the first assignment data represents an assignment between the logical memory addresses being addressable by a host through the memory controller circuit and physical memory addresses of the NVM, and wherein updating the first assignment data results in the assignment represented by the first assignment data coinciding with an assignment between the logical memory addresses and physical addresses of the NVM that is currently actually used by the memory controller circuit for addressing the NVM, and which is at least partly stored in the VM as respective second assignment data.

14. The non-volatile memory system of claim 12, the system further comprising:
the NVM; and
the VM.

15. The non-volatile memory system of claim 12, wherein the predefined criterion is fulfilled when an impairment of a power supply providing power to at least one of the memory controller circuit or the VM is indicated.

16. The non-volatile memory system of claim 14, wherein the impairment of the power supply providing power to at least one of the memory controller circuit or the VM is indicated when the impairment is already present, upcoming, or imminent.

17. The non-volatile memory system of claim 14, wherein the host is signal-connected to the memory controller circuit, and wherein the impairment of the power supply providing power to at least one of the memory controller circuit or the VM is determined based upon a signal received by the memory controller circuit from the host.

18. The non-volatile memory system of claim 16, wherein the signal received by the memory controller circuit from the host is selected from a group consisting of:
a control command specified in accordance with an industry standard; an application specific control command; and a control command specifically defined for initiating the update of the first assignment data stored in the NVM.

19. The non-volatile memory system of claim 14, wherein the impairment of the power supply providing power to at least one of the memory controller circuit or the VM is determined by monitoring operation of the power supply by the memory controller circuit.

20. The non-volatile memory system of claim 14, wherein upon determination of the impairment of the power supply providing power to at least one of the memory controller circuit or the VM, power from an energy storage is used instead of or in addition to the power supply for supplying power to the memory controller circuit and the VM during updating of the first assignment data stored in the NVM.

21. The non-volatile memory system of claim 19, the system further comprising:
the energy storage, wherein the energy storage is independent from the power supply.

22. The non-volatile memory system of claim 12, wherein the predefined criterion is a function of a degree of deviation between the first assignment data and the second assignment data.

23. The non-volatile memory system of claim 21, wherein the function of the degree of deviation between the first assignment data and the second assignment data is a function of one or more of the following variables:
a number of write operations in the NVM that have occurred since the last update of the first assignment data stored in the NVM;
a number of erasure operations in the NVM that have occurred since the last update of the first assignment data stored in the NVM;
a period of time that has elapsed since the last update of the first assignment data stored in the NVM; and
a data quantity indicating a degree of change in the second assignment data since the last update of the first assignment data stored in the NVM.

24. The non-volatile memory system of claim 21, wherein the predefined criterion is configurable by way of a parameterization in relation to the degree of deviation of the first assignment data from the second assignment data.

25. The non-volatile memory system of claim 12, wherein the predefined criterion is a combination of both a function of a degree of deviation between the first assignment data and the second assignment data, and an operational status of a power supply providing power to at least one of the memory controller circuit or the VM is indicated; and wherein the predefined criterion is fulfilled when both a predefined degree of deviation between the first assignment and the second assignment is determined and an impairment of the power supply providing power to at least one of the memory controller circuit or the VM is indicated.

26. The non-volatile memory system of claim 12, wherein updating the first assignment data stored in the NVM includes transferring at least a portion of the second assignment data from the VM to the NVM such that the portion of the second assignment data replaces a portion of the first assignment data in the NVM.

27. A computer program stored on a non-transient medium and configured to be executed on one or more processors of a memory controller system for controlling a non-volatile digital information memory (NVM), and to cause the memory controller system to:
perform an updating process where first assignment data being stored in the NVM and representing an assignment between the logical memory addresses being addressable by a host through a memory controller circuit and physical memory addresses of the NVM is updated such that the assignment represented by the first assignment data coincides with an assignment between the logical memory addresses and physical addresses of the NVM that is currently actually used by the memory controller circuit for addressing the NVM, and which is at least partly stored in a volatile memory (VM) as respective second assignment data;
perform an examination process in which a determination is made, as to whether a pre-defined criterion is met that characterizes a potential loss of the second assignment data with regard to its occurrence and/or the degree of deviation of the assignment represented by the second assignment data from the assignment represented by the first assignment data; and
wherein the updating process is started upon determining that the criterion is met.
